(19) United States
(12) Patent Application Publication
(10) Pub. No.: US 2005/0287705 A1
(43) Pub. Date: Dec. 29, 2005

(54) Flip chip on leadframe package and method for manufacturing the same

(75) Inventor: Chaur-Chin Yang, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/138,406

(22) Filed: May 27, 2005

(30) Foreign Application Priority Data
Jun. 25, 2004 (TW) 93118581

(51) Int. Cl. H01L 21/60

(52) U.S. Cl. 438/108; 438/123; 438/615

(57) ABSTRACT

A flip chip on leadframe package includes a leadframe, a non-flow underfilling material and a flip chip. The leadframe has a plurality of inner leads. Each inner lead has an upper surface and a lower surface. A coating region is defined on the upper surfaces. The non-flow underfilling material is formed on the coating region. The chip has an active surface with a plurality of bumps. The bumps pass through the non-flow underfilling material to be connected to the coating region of the upper surfaces. Only the leadframe inside the coating region are wettable with the bumps for controlling the collapse of the bumps.

This application claims the benefit of Taiwan application Serial No. 93118581, filed Jun. 25, 2004, the subject matter of which is incorporated herein by reference.

### BACKGROUND OF THE INVENTION

1. Field of the Invention

The invention relates in general to a flip chip package, and more particularly to a flip chip on leadframe package.

2. Description of the Related Art

A flip chip on leadframe is achieved by bonding a plurality of bumps disposed on the active surface of a flip chip onto a plurality of leads of a leadframe to replace the practice of using bonding wire for electrical connection. However, the conventional leadframe for flip chip bonding is slightly different from the conventional leadframe for wire bonding. The leadframe for flip chip bonding uses the inner ends of the upper surfaces of a plurality of leads to be correspondingly bonded to the bumps of the chip. The upper surfaces of the leads have a design to prevent the solder flux from being spread over, so that the bumps of the chip would not spread over the other parts of the leads during soldering. U.S. patent Publication No. 6,593,545 discloses that a non-wettable barrier is obtained on each inner lead of the leadframe through the cauterization of laser ray, so that a wettable area (bump bonding region) is defined on each inner lead, and that the height of bumps of the chip would be controlled.

Besides, a “flip chip quad flat leadless frame” disclosed in Taiwan Patent Publication No. 463342, mainly includes a plurality of leads, a chip and a packaging material. Each lead respectively has a first surface and a corresponding second surface. The first surfaces of the leads respectively have a solder mask layer with a plurality of apertures, so that a bump region is defined on each lead. The chip has an active surface and a corresponding rear surface. The active surface has a plurality of solder pads. Each solder pad has a bump respectively corresponding to the aperture of the solder mask layer and connected to the lead. The apertures of the solder mask layer are used to limit the wet bonding area of the bumps of the chip on 15 the leads. The packaging material encapsulates the leads and the chip and exposes the second surface of the leads. The solder mask layer is easily over-flown to the lower surface of the leads, so that the leadframe may tarnish the machinery or affect the upper plate bonding of the flip chip quad flat leadless leadframe. Moreover, for a solder mask layer to be formed on the leadframe, several manufacturing processes such as printing, exposing, developing, and etching, adding more to manufacturing costs.

### SUMMARY OF THE INVENTION

It is therefore a main object of the invention to provide a flip chip on leadframe package. A non-flow underfilling material is formed on a coating region of an upper surface of a plurality of inner leads. The bumps of a flip chip pass through the non-flow underfilling material to be bonded on the upper surface of the inner leads. The non-flow underfilling material is used to limit the bonding area between the bumps and the inner leads so that only the leadframe inside the coating region are wettable with the bumps and that the bump height and collapse are controlled.

It is therefore a second object of the invention to provide a manufacturing method of flip chip on leadframe package. A non-flow underfilling material is formed on a coating region of an upper surface of a plurality of inner leads for a flip chip to be bonded on the leadframe. A plurality of bumps of the flip chip pass through the non-flow underfilling material to be bonded on the inner leads. The non-flow underfilling material is used to limit the bonding area between the bumps and the inner leads so that only the leadframe inside the coating region are wettable with the bumps and that the bump height and collapse are controlled.

The flip chip on leadframe package according to the invention includes a leadframe, a non-flow underfilling material and a flip chip. The leadframe has a plurality of inner leads. Each inner lead has an upper surface and a lower surface. A coating region is defined on the upper surfaces. The non-flow underfilling material is formed on the coating region. The non-flow underfilling material includes a thermosetting resin and a solder flux. The flip chip has an active surface with a plurality of bumps. The flip chip is pressed under the non-flow underfilling material with the active surface facing towards the inner leads, so that the bumps pass through the non-flow underfilling material to be connected to the coating region of the upper surfaces. The non-flow underfilling material enables the leadframe inside the coating region are wettable with the bumps for controlling the bump height and collapse.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a cross-sectional view of a flip chip on leadframe package according to a first embodiment of the invention;

FIG. 2 is a partial front view of a leadframe of a flip chip on leadframe package according to a first embodiment of the invention;

FIGS. 3A-3D are sectional views of a leadframe during the manufacturing process, showing a manufacturing method of flip chip on leadframe package according to a first embodiment of the invention;

FIG. 4 is a front view of a flip chip placed on the leadframe for bonding during a manufacturing method of flip chip on leadframe package according to a first embodiment of the invention;

FIG. 5 is a cross-sectional view along the sectional line 5-5 of FIG. 4 during a manufacturing method of flip chip on leadframe package according to a first embodiment of the invention;

FIG. 6 is a partial front view of a leadframe of a flip chip on leadframe package according to a second embodiment of the invention;

FIG. 7 is a cross-sectional view along the sectional line 7-7 of FIG. 6 during a manufacturing method of flip chip on leadframe package according to a second embodiment of the invention; and

FIG. 8 is a cross-sectional view along the sectional line 8-8 of FIG. 6 during a manufacturing method of flip chip on leadframe package according to a second embodiment of the invention according to the invention second embodiment.

### DETAILED DESCRIPTION OF THE INVENTION

Referring to the accompanying drawings, the invention is exemplified by the embodiment disclosed below.

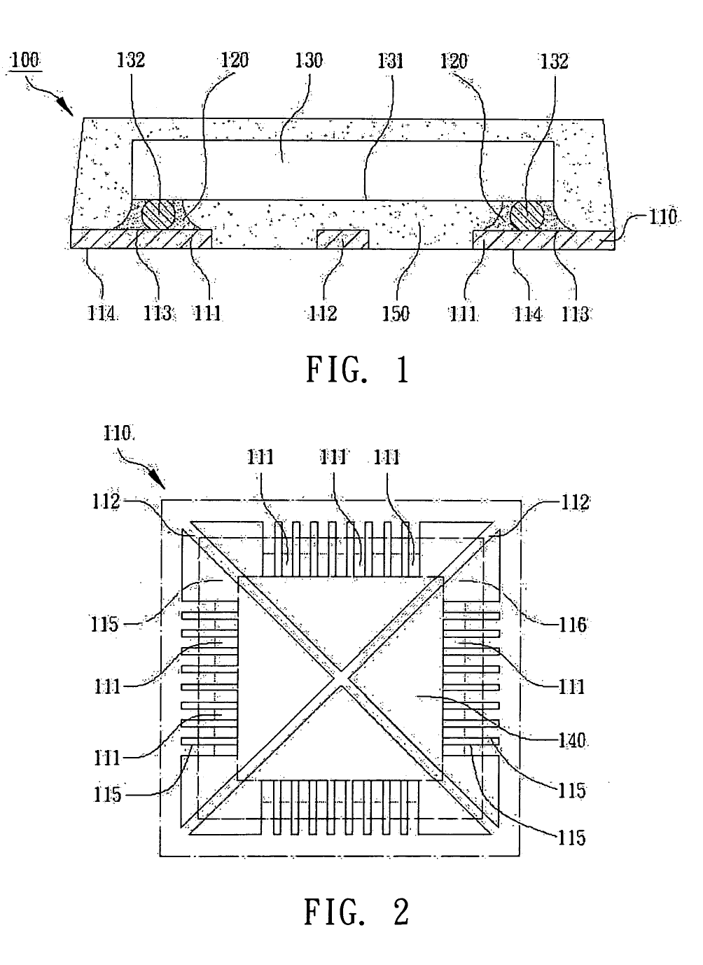

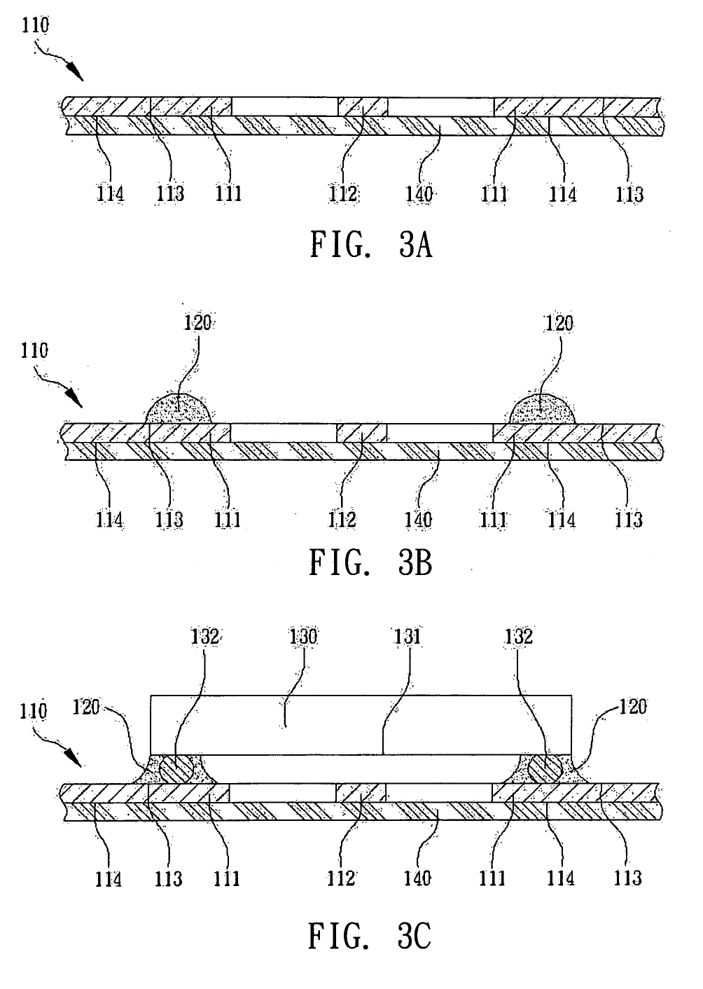

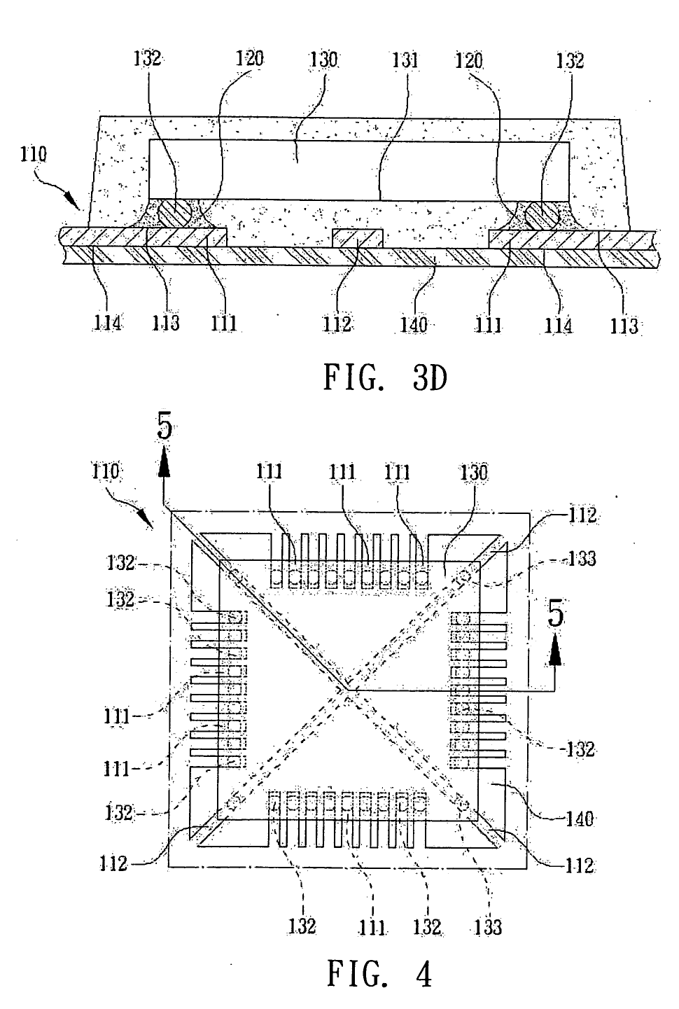

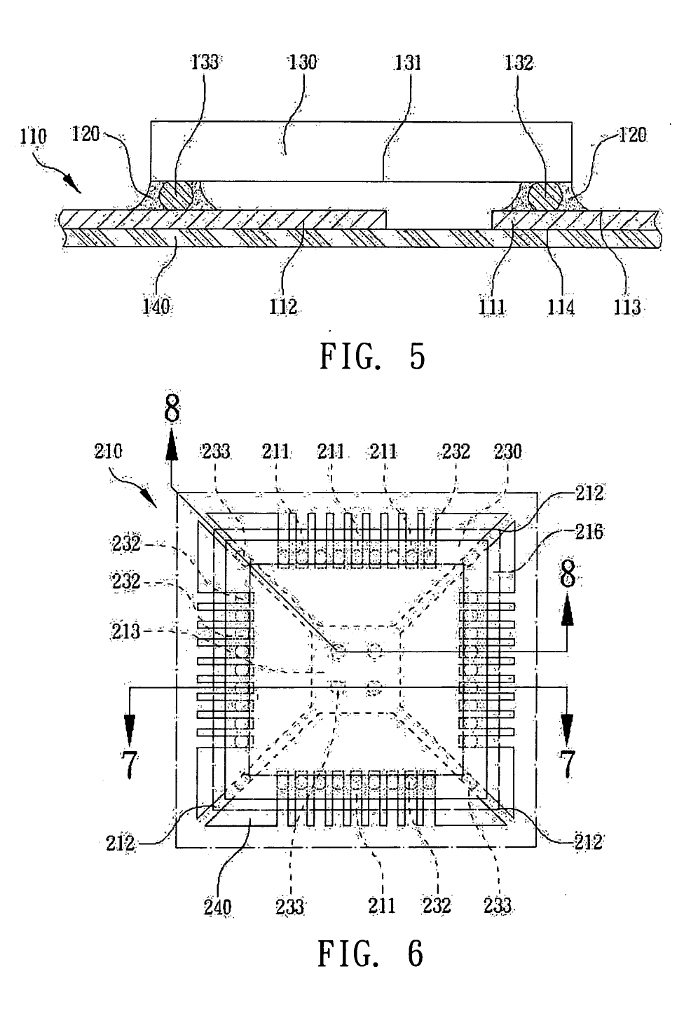

Referring to FIG. 1 according to a first embodiment of the invention, a flip chip on leadframe package 100 mainly including a leadframe 110, a non-flow underfilling material 120 and a flip chip 130 is shown. The front view of the leadframe 110 is shown in FIG. 2. The leadframe 110 can be a leadless leadframe or a quad flat package (QFP) leadframe with outer leads. The embodiment is exemplified by a leadless leadframe. The leadframe 110 has a plurality of inner leads 111 and a plurality of tie bars 112. In the present embodiment, the tie bars 112 intersect to form a cross. Each inner lead 111 has an upper surface 113, a lower surface 114 and a plurality of side walls 115 positioned between the upper surface 113 and the lower surface 114. The upper surfaces 113 have a ring-shaped coating region 116. Preferably, a film 140 is attached on the lower surface 114 of the inner leads 111 as shown in FIG. 3D. After the package 100 is completed, the film 140 is removed for exposing the lower surface 114 of the inner leads 111. The non-flow underfilling material 120 can be formed on the coating region 116 through dispensing or printing. Preferably, the non-flow underfilling material 120 is disposed on and surrounds the leadframe 110, so that the non-flow underfilling material 120 can cover the side walls 115 between adjacent inner leads 111. The non-flow underfilling material 120 includes a thermosetting resin and a solder flux. The flip chip 130 has an active surface 131 with a plurality of electricity conductive bumps 132 and a plurality of electricity non-conductive dummy bumps 133 as shown in FIG. 5. According to the present embodiment, the bumps 132 are formed around the active surface 131, while the dummy bumps 133 are formed at the corners of the active surface 131. The flip chip 130 is pressed under the non-flow underfilling material 120 with the active surface 131 facing towards the upper surface 113 of the inner leads 111, so that the bumps 132 pass through the non-flow underfilling material 120 to be bonded onto the coating region 116 on the upper surface 113 of the inner leads 111, and that the dummy bumps 133 also pass through the non-flow underfilling material 120 to be bonded onto the tie bars 112 to enhance the bonding intensity between the flip chip 130 and the leadframe 110. In the present embodiment, the package 100 further includes a molding compound 150, which encapsulates the non-flow underfilling material 120, fixes the inner leads 111 and the flip chip 130, and exposes the lower surface 114 of the inner leads 111 to be bonded onto an external circuit board (not shown in the diagram.

The invention uses the non-flow underfilling material 120 to form the coating region 116 on the upper surface 113 of the inner leads 111. The flip chip 130 is pressed under the non-flow underfilling material 120, so that the bumps 132 of the flip chip 130 pass through the non-flow underfilling material 120 to be bonded onto the inner leads 111. The non-flow underfilling material 120 limits the bonding area between the bumps 132 and the inner leads 111, so that only the leadframe 110 inside the coating region 116 are wettable with the bumps 132 and spread, and that the collapse and height of the bumps 132 are controllable.

The manufacturing method of the flip chip on leadframe package 100 is disclosed below.

At first, referring to FIG. 2 and FIG. 3A, a leadframe 110 having a plurality of inner leads111 and a plurality of tie bars 112 is provided. Each inner lead 111 has an upper surface 113 and a lower surface 114. A coating region 116 is defined on the upper surfaces 113. A film 140 is attached on the lower surface 114 of the inner leads 111. Further referring to FIG. 3B, a non-flow underfilling material 120 is formed on the coating region 116. The non-flow underfilling material 120 can cover up the side walls 115 positioned between adjacent inner leads 111. The non-flow underfilling material 120 includes a thermosetting resin and a solder flux. The non-flow underfilling material 120 is formed at the front end of the inner leads 111 through printing or dispensing. Further referring to FIG. 3C, FIG. 4 and FIG. 5, a flip chip 130 is placed onto the leadframe 110 for bonding. The flip chip 130 has an active surface 131 and is pressed under the non-flow underfilling material 120 with the active surface 131 facing towards the upper surface 113 of the inner leads 111, so that the bumps 132 and the dummy bumps 133 pass through the non-flow underfilling material 120 to be respectively connected to the inner leads 111 and the tie bars 112. After a reflow step, the flip chip 130 are respectively connected to the coating region 116 and the tie bars 112 on the upper surface 113 of the inner leads 111 via the bumps 132 and the dummy bumps 133. Under the function of the solder flux of the non-flow underfilling material 120, the bumps 132 and the dummy bumps 133 can pass through the non-flow underfilling material 120 to be soldered with the leadframe 110. Further referring to FIG. 3D, a molding compound 150 is formed on the upper surface 113 of the inner leads 111 for encapsulating the non-flow underfilling material 120 and the flip chip 130, and fixing the inner leads 111 and the flip chip 130. Then, as shown in FIG. 1, the film 140 is removed for exposing the lower surface 113 of the inner leads 111 and the bottom surface of the molding compound 150.

Since that the film 140 is attached on the lower surface 114 of the inner leads 111 and that the flip chip 130 is pressed under the non-flow underfilling material 120, when the bumps 132 and the dummy bumps 133 pass through the non-flow underfilling material 120 to be bonded onto the upper surface 113 of the inner leads 111 and the tie bars 112, the film 140 would not tarnish the lower surface 114 of the inner leads 111 due to the overflow of the non-flow underfilling material 120. Moreover, the non-flow underfilling material 120 limits the bonding area between the bumps 132 and the inner leads 111, so that the collapse and the height of the bumps 132 are controllable.

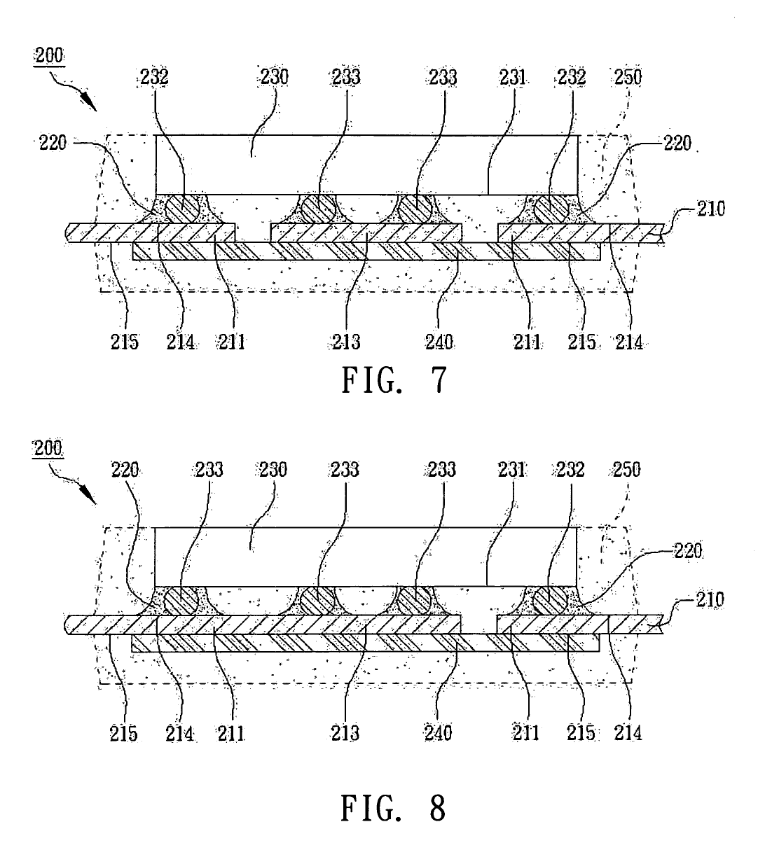

Referring to FIGS. 6, 7 and 8 according to a second embodiment of the invention, a flip chip on leadframe package 200 mainly including a leadframe 210, a non-flow underfilling material 220 and a flip chip 230 is provided. In the present embodiment, the leadframe 210 is a quad flat package (QFP) leadframe with leads. The leadframe 210 has a plurality of inner leads 211 and a plurality of tie bars 212 and a heat spreader 213. The heat spreader 213 is connected to the tie bars 212. Each inner lead 211 has an upper surface 214 and a lower surface 215. A coating region 216 is defined on the upper surfaces 214. A film 240 is attached on the lower surfaces 214 as shown in FIG. 7. The non-flow underfilling material 220, formed on the coating region 216, includes a thermosetting resin and a solder flux. The flip chip 230 has an active surface 231 with a plurality of electricity conductive bumps 232 and a plurality of electricity non-conductive dummy bumps 233. The bumps 232 are formed around the active surface 231 and pass through the non-flow underfilling material 220 to be bonded onto coating region 216 on the upper surface 214 of the inner leads 211. The dummy bumps 233 are formed on the corners and the central region of the active surface 231 and are bonded onto the tie bars 212 and the heat spreader 213 positioned under the flip chip 230 to enhance the bonding intensity between the flip chip 230 and the leadframe 210 and improve the heat dispersion of the package 200. The package 200 further includes a molding compound 250, which encapsulates the non-flow underfilling material 220, the flip chip 230, the inner leads 211, the tie bars 212 and the heat spreader 213, and further fixes the inner leads 211 and the flip chip 230.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A manufacturing method of flip chip on leadframe package, comprising:
providing a leadframe, wherein the leadframe has a plurality of inner leads, each inner lead has an upper surface and a lower surface, and a coating region is defined on the upper surfaces;
forming a non-flow underfilling material on the coating region;
placing a flip chip on the leadframe, wherein the flip chip has an active surface with a plurality of bumps, and the bumps pass through the non-flow underfilling material; and
conducting a reflowing process for bonding the bumps on the inner leads.

2. The method according to claim 1, further comprising attaching a film on the lower surface of the inner leads after the step of providing a leadframe.

3. The method according to claim 2, further comprising removing the film for exposing the lower surface of the inner leads following the step of conducting the reflowing process.

4. The method according to claim 1, further comprising forming a molding compound on the upper surface of the inner leads for encapsulating the non-flow underfilling material and fixing the inner leads and the flip chip after the step of conducting the reflow process.

5. The method according to claim 1, wherein the non-flow underfilling material forms the coating region on the inner leads by using printing or dispensing.

6. The method according to claim 1, wherein the non-flow underfilling material comprises a thermosetting resin and a solder flux.
